(19) United States
(12) Patent Application Publication
(10) Pub. No.: US 2026/0066860 A1
(43) Pub. Date: Mar. 5, 2026

(54) Common-Mode Control of Preamplifier Circuit

(71) Applicant: Omni Design Technologies, Inc., Milpitas, CA (US)

(72) Inventors: Manar El-Chammas, Austin, TX (US); Svilen Mintchev, Cedar Park, TX (US)

(21) Appl. No.: 18/825,298

(22) Filed: Sep. 5, 2024

(51) Int. Cl. H03F 3/45; H03M 1/08

(52) U.S. Cl. CPC H03F 3/45183; H03F 3/45748; H03M 1/08

(57) ABSTRACT

A preamplifier includes an operational transconductance amplifier, a first-type metal-oxide-semiconductor (MOS) transistor have a gate electrically coupled to the OTA output; a first second-type MOS transistor; a second second-type MOS transistor electrically connected in parallel with the first second-type MOS transistor; a first load resistor electrically connected in series with a drain of the first second-type MOS transistor that has a first output voltage; a second load resistor electrically connected in series with a drain of the second second-type MOS transistor that has a second output voltage; a tail node electrically connected to a source of the first second-type MOS transistor, a source of the second second-type MOS transistor, and a drain of a third second-type MOS transistor; a common-mode feedback circuit electrically coupled to the first and second output voltages and to a first OTA input; and a reference voltage electrically coupled to a second OTA input.

### TECHNICAL FIELD

This application relates generally to preamplifiers such as for comparators for analog-to-digital converters.

### BACKGROUND

An analog-to-digital converter (ADC) comparator 10 often includes a preamplifier 100 and a clocked latch 110, for example as illustrated in FIG. 1. The preamplifier creates gain between the latch and the comparator inputs. The gain helps in reducing the input referred offset and noise. It is also beneficial for the clocked comparator latch to work with fixed input common mode voltage, thus having a relatively constant threshold of operation. The optimized latch input common-mode voltage results also in good amount of latch gain being developed over time before the regeneration process starts. The preamplifier can be designed to provide stable latch input common-mode voltage.

It is often desired to calibrate the comparator for achieving low input referred offset below the values that can be achieved otherwise by placing a preamplifier alone in front of the latch. It turns out that a relatively constant preamplifier output common-mode voltage helps with achieving low residual offset after calibration compared with the case when the preamplifier output common-mode voltage were to be left varying with process-voltage-temperature (PVT).

Often in a resistively loaded preamplifier, the common-mode control is provided by biasing the differential pair of the preamplifier with a current having V/R behavior, as illustrated in the preamplifier 20 in FIG. 2. This design relies on close matching between the preamplifier loading resistors and the resistor inside the block generating the bias current, as well as a constant voltage Vref. This approach should result in a nominally constant output common-mode voltage. At the same time the preamplifier resistor values and the differential pair PMOS (P-channel metal-oxide-semiconductor) transistors' sizes are chosen to provide the required gain and bandwidth. Also, the current in the biasing PMOS (tail device) and/or the value of the load resistors can be programmable, thus programming the bandwidth of the preamplifier while keeping the nominal output common-mode voltage the same.

In addition, the comparator offset is calibrated with the goal of keeping the input referred offset below a certain value with devices process and statistical variations. This approach will be susceptible to matching imperfections resulting in variations of the common mode voltage to the comparator latch inputs. Especially troublesome are the cases when the latch input differential pair is designed with NMOS transistors, and the mismatches bring the preamplifier output common-mode voltage lower than the optimal value. When the latch is clocked before making a decision, the kick-back into the preamplifier load resistors will result in even lower instantaneous common-mode voltage.

FIG. 3 is a circuit diagram of a preamplifier 30 in which common-mode voltage feedback is introduced as another approach to control common-mode voltage. An operational transconductance amplifier (OTA) is used to control the current of the NMOS transistors M1 and M2 in such a way so as to impose the voltage Vref in the middle point of the load resistors RL. If the bias current imposed by the tail transistor MP3 remains the same as defined by the gain and bandwidth requirements, then this scheme does not change those parameters but assures a good output common-mode voltage stability. Since MP3 size could be programmable as explained above, it is more convenient to control the common-mode voltage from the NMOS side and keep the current programmability and common-mode voltage control separated. A drawback, however, is that M1 and M2 introduce extra noise at the outputs of the preamplifier and thus this approach is not suitable for designs requiring low input referred noise.

FIG. 4 is a circuit diagram of a preamplifier 40 according to another approach. Here the controlling device M1 is connected at a common-mode point ncm and the noise it injects into the preamplifier appears as common-mode to the outputs and is generally rejected differentially. The nominally matched transistor pairs MP7/MP4 and MP8/MP5 extract the preamplifier output common-mode voltage, level-shifted up by a gate-threshold voltage (VGS) and the OTA compares it with a similarly level-shifted reference voltage Vref. The negative feedback loop drives the difference between the inputs of the OTA towards zero thus imposing the Vref value as the common-mode output voltage of the preamplifier. If the preamplifier output common-mode voltage is too high, the OTA drives M1 stronger, thus lowering the output common-mode voltage. Conversely, if the output common-mode voltage is too low, the OTA reduces the drive to M1, thus increasing the output common-mode voltage. A drawback in this circuit appears when the uncontrolled output common-mode voltage is so high that the OTA has to drive M1 to the point where M1 is deep into the triode region and thus is effectively a short circuit to ground. In this situation the loop control is greatly eliminated, and no further common-mode control is possible.

### SUMMARY

Example embodiments described herein have innovative features, no single one of which is indispensable or solely responsible for their desirable attributes. The following description and drawings set forth certain illustrative implementations of the disclosure in detail, which are indicative of several exemplary ways in which the various principles of the disclosure may be carried out. The illustrative examples, however, are not exhaustive of the many possible embodiments of the disclosure. Without limiting the scope of the claims, some of the advantageous features will now be summarized. Other objects, advantages, and novel features of the disclosure will be set forth in the following detailed description of the disclosure when considered in conjunction with the drawings, which are intended to illustrate, not limit, the invention.

An aspect of the invention is directed to a preamplifier comprising an operational transconductance amplifier (OTA) having first and second inputs and an output; a first-type metal-oxide-semiconductor (MOS) transistor have a gate electrically coupled to the output of the OTA; a first second-type MOS transistor; a second second-type MOS transistor, the first and second second-type MOS transistors electrically connected in parallel with each other, a first load resistor electrically connected in series with a drain of the first second-type MOS transistor, the drain of the first second-type MOS transistor having a first output voltage; a second load resistor electrically connected in series with a drain of the second second-type MOS transistor, the drain of the second second-type MOS transistor having a second output voltage; a third second-type MOS transistor; a tail node electrically connected to a source of the first second-type MOS transistor, a source of the second second-type MOS transistor, and a drain of the third second-type MOS transistor; a common-mode feedback circuit electrically coupled to the first and second output voltages and to the first input of the OTA; and a reference voltage electrically coupled to the second input of the OTA, wherein the first-type MOS transistor is of an opposite type to each second-type MOS transistor.

In one or more embodiments, the first-type MOS transistor is an N-channel MOS (NMOS) transistor and each second-type MOS transistor is a P-channel MOS (PMOS) transistor. In one or more embodiments, the first-type MOS transistor is a PMOS transistor and each second-type MOS transistor is an NMOS transistor.

In one or more embodiments, the common-mode feedback circuit comprises a fourth second-type MOS transistor having a gate electrically coupled to the first output voltage; a fifth second-type MOS transistor having a gate electrically coupled to the second output voltage; a sixth second-type MOS transistor; a seventh second-type MOS transistor; a first resistor having first and second terminals, the first terminal electrically connected to a source of the fourth second-type MOS transistor and to a drain of the sixth second-type MOS transistor, the second terminal electrically connected to a common-mode node; and a second resistor having first and second terminals, the first terminal of the second resistor electrically connected to a source of the fifth second-type MOS transistor and to a drain of the seventh second-type MOS transistor, the second terminal electrically connected to the common-mode node, the common-mode node electrically coupled to the first input of the OTA. In one or more embodiments, the preamplifier further comprises an eighth second-type MOS transistor having a gate electrically coupled to the reference voltage and a source electrically connected to a reference node; and a nineth second-type MOS transistor having a drain electrically connected to the reference node, the reference node electrically coupled to the second input of the OTA.

In one or more embodiments, the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

Another aspect of the invention is directed to a preamplifier comprising an OTA having first and second inputs and an output; a first first-type MOS transistor have a gate electrically coupled to the output of the OTA; a first second-type MOS transistor; a second second-type MOS transistor, the first and second second-type MOS transistors electrically connected in parallel with each other; a first load resistor electrically connected in series with a drain of the first second-type MOS transistor, the drain of the first second-type MOS transistor having a first output voltage; a second load resistor electrically connected in series with a drain of the second second-type MOS transistor, the drain of the second second-type MOS transistor having a second output voltage; a third second-type MOS transistor; a tail node electrically connected to a source of the first second-type MOS transistor, a source of the second second-type MOS transistor, and a drain of the third second-type MOS transistor; a second first-type MOS transistor have a gate electrically coupled to the output of the OTA and a drain electrically connected to the tail node; a third first-type MOS transistor have a gate and a drain electrically connected to a source of the second first-type MOS transistor; a common-mode node electrically connected to the first and second load resistors and to a drain of the first first-type MOS transistor; a common-mode feedback circuit electrically coupled to the first and second output voltages and to the first input of the OTA; and a reference voltage electrically coupled to the second input of the OTA, wherein each first-type MOS transistor is of an opposite type to each second-type MOS transistor.

In one or more embodiments, each first-type MOS transistor is an NMOS transistor and each second-type MOS transistor is a PMOS transistor. In one or more embodiments, each first-type MOS transistor is a PMOS transistor and each second-type MOS transistor is an NMOS transistor.

In one or more embodiments, the common-mode node is a first common-mode node, and the common-mode feedback circuit comprises a fourth second-type MOS transistor having a gate electrically coupled to the first output voltage; a fifth second-type MOS transistor having a gate electrically coupled to the second output voltage; a sixth second-type MOS transistor; a seventh second-type MOS transistor; a first resistor having first and second terminals, the first terminal electrically connected to a source of the fourth second-type MOS transistor and to a drain of the sixth second-type MOS transistor, the second terminal electrically connected to a second common-mode node; and a second resistor having first and second terminals, the first terminal of the second resistor electrically connected to a source of the fifth second-type MOS transistor and to a drain of the seventh second-type MOS transistor, the second terminal electrically connected to the second common-mode node, the second common-mode node electrically coupled to the first input of the OTA.

In one or more embodiments, the preamplifier further comprises an eighth second-type MOS transistor having a gate electrically coupled to the reference voltage and a source electrically connected to a reference node; and a nineth second-type MOS transistor having a drain electrically connected to the reference node, the reference node electrically coupled to the second input of the OTA. In one or more embodiments, the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

Another aspect of the invention is directed to a preamplifier comprising an OTA having first and second inputs and an output; a first first-type MOS transistor have a gate electrically coupled to the output of the OTA; a first second-type MOS transistor; a second second-type MOS transistor, the first and second second-type MOS transistors electrically connected in parallel with each other; a first load resistor electrically connected in series with a drain of the first second-type MOS transistor, the drain of the first second-type MOS transistor having a first output voltage; a second load resistor electrically connected in series with a drain of the second second-type MOS transistor, the drain of the second second-type MOS transistor having a second output voltage; a third second-type MOS transistor; a tail node electrically connected to a source of the first second-type MOS transistor, a source of the second second-type POS transistor, and a drain of the third second-type MOS transistor; a second first-type MOS transistor have a gate electrically coupled to the output of the OTA and a drain electrically connected to the tail node; a third first-type MOS transistor have a gate and a drain electrically connected to a source of the second first-type MOS transistor; a first common-mode node electrically connected to the first and second load resistors and to a drain of the first first-type MOS transistor; a first resistor having a first terminal electrically connected to a drain of the first second-type MOS transistor; a second resistor having a second terminal electrically connected to a drain of the second second-type MOS transistor; a second common-mode node electrically connected to a second terminal of the first resistor, a second terminal of the second resistor, and the first input of the OTA; and a reference voltage electrically coupled to the second input of the OTA, wherein each first-type MOS transistor is of an opposite type than each second-type MOS transistor.

Another aspect of the invention is directed to each first-type MOS transistor is an NMOS transistor and each second-type MOS transistor is a PMOS transistor. Another aspect of the invention is directed to each first-type MOS transistor is a PMOS transistor and each second-type MOS transistor is an NMOS transistor.

Another aspect of the invention is directed to the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

Another aspect of the invention is directed to a comparator for an analog-to-digital converter comprising a preamplifier as described herein and a clocked latch, wherein the first and second output voltages are electrically coupled to first and second inputs, respectively, of the clocked latch.

### BRIEF DESCRIPTION OF THE DRAWINGS

For a fuller understanding of the nature and advantages of the concepts disclosed herein, reference is made to the detailed description of preferred embodiments and the accompanying drawings.

FIG. 1 is a block diagram of a comparator for an analog-to-digital converter.

FIG. 2 is a circuit diagram of a preamplifier having a first known approach to control common-mode voltage.

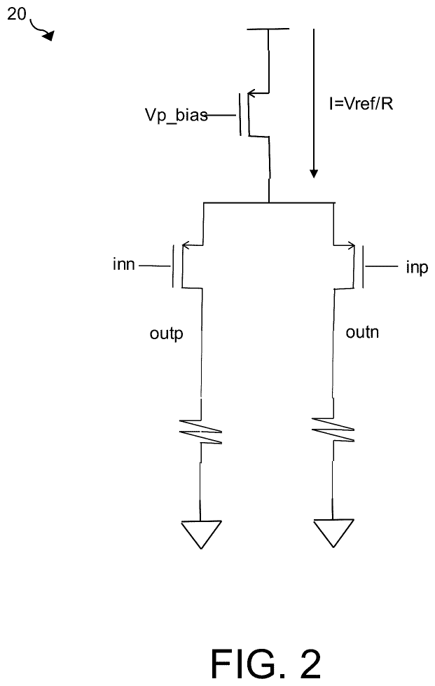

FIG. 3 is a circuit diagram of a preamplifier having a second known approach to control common-mode voltage.

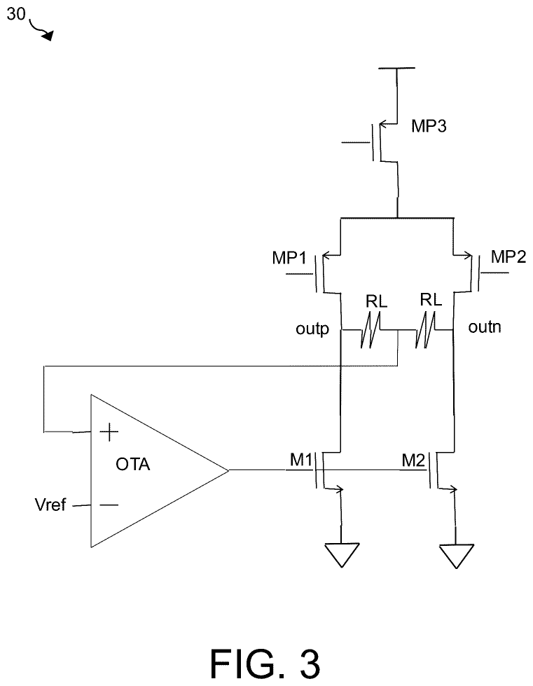

FIG. 4 is a circuit diagram of a preamplifier having a third known approach to control common-mode voltage.

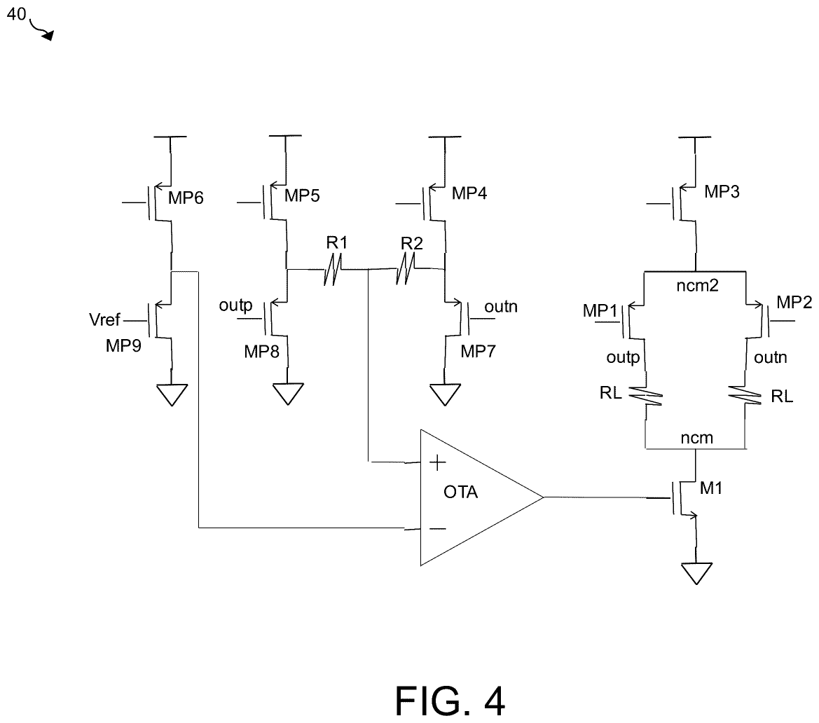

FIG. 5 is a circuit diagram of a preamplifier according to one or more embodiments.

FIG. 6 is a circuit diagram of a preamplifier according to one or more embodiments.

FIG. 7 is a circuit diagram of a preamplifier according to one or more embodiments.

FIG. 8 is a circuit diagram of a preamplifier according to one or more embodiments.

FIG. 9 is a circuit diagram of a preamplifier according to one or more embodiments.

FIG. 10 is a circuit diagram of a preamplifier according to one or more embodiments.

### DETAILED DESCRIPTION

We propose a common-mode voltage regulation scheme that injects a regulation current in points of the circuit where no (or minimal) extra noise is introduced, that does not affect (or only minimally affects) the predefined preamplifier gain, that does not introduce (or only minimally introduces) extra differential loading, and that reduces the output common-mode voltage variation which results in lower still variation of the residual after calibration input referred offset of the comparator.

This approach of common-mode voltage regulation could be used under different circumstances, not necessarily related to comparators where such regulation is needed.

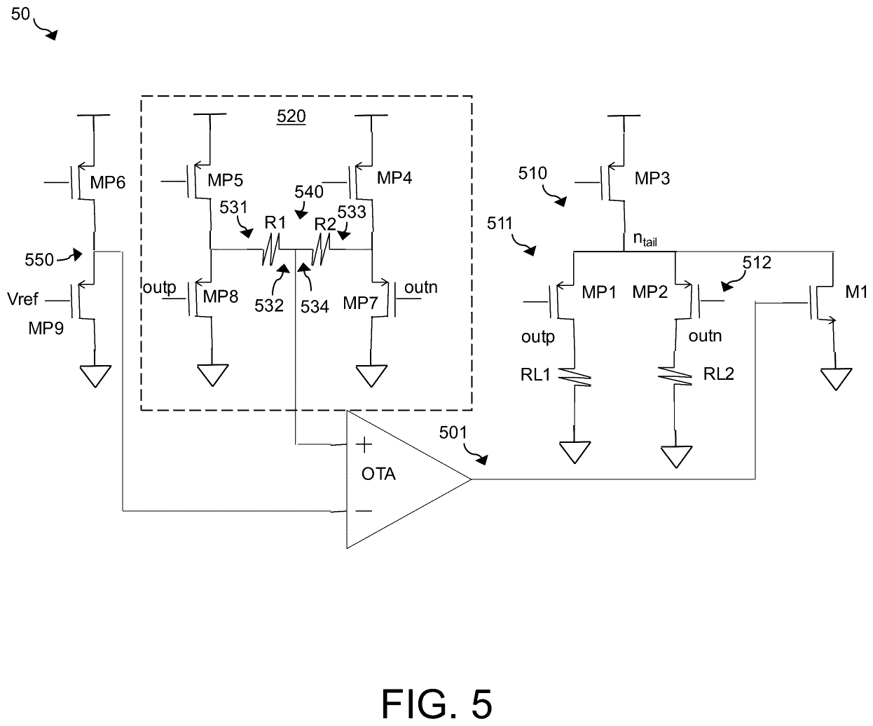

FIG. 5 is a circuit diagram of a preamplifier 50 according to one or more embodiments. The preamplifier 50 includes an operational transconductance amplifier (OTA), an NMOS (N-channel metal-oxide-semiconductor) transistor M1, a plurality of PMOS (P-channel metal-oxide-semiconductor) transistors MP1-MP9, load resistors RL1, RL2, and resistors R1, R2.

The output 501 of the OTA is electrically connected to a gate of the NMOS transistor M1. A drain of M1 is electrically connected or electrically coupled to a tail node nₜₐᵢₗ. A source of M1 is electrically connected to signal ground. A long-tailed differential pair 510 is electrically connected to the tail node nₜₐᵢₗ. A first side 511 of the differential pair 510 includes MP1 and a first load resistor RL1 electrically connected in series with a drain of MP1. The first load resistor RL1 is also electrically connected in series with signal ground. A second side 512 of the differential pair 510 includes MP2 and a second load resistor RL2 electrically connected in series with a drain of MP2. The second load resistor RL2 is also electrically connected in series with signal ground. The drain of MP1 has a positive output voltage outp. The drain of MP2 has a negative output voltage outn. The first and second load resistors RL1, RL2 are the same or substantially the same. A drain of bias transistor MP3 is electrically connected in series with the tail node nₜₐᵢₗ.

A feedback circuit 520 is electrically coupled to the output voltages outp, outn. The feedback circuit 520 includes PMOS transistors MP4, MP5, MP7, MP8 and resistors R1, R2.

A gate of MP8 is electrically coupled to the output voltage outp. A source of MP8 is electrically connected to a first terminal 531 of the resistor R1 and to a drain of MP5. A drain of MP8 is electrically connected to signal ground. A gate of MP7 is electrically coupled to the output voltage outn. A source of MP7 is electrically connected to a first terminal 533 of the resistor R2 and to a drain of MP4. A second terminal 532 of the first resistor R1 and a second terminal 534 of the second resistor R2 are electrically connected to a common-mode node 540. The common-mode node 540 is electrically connected in series with the second terminal 532 of the first resistor R1 and the second terminal 534 of the second resistor R2. The first and second resistors R1, R2 can be the same or substantially the same. The common-mode node 540 is electrically connected to a positive input of the OTA. The PMOS transistors MP4, MP5, MP7, and MP8 and resistors R1, R2 extract the preamplifier output common-mode voltage and feed it back to the OTA.

A gate of MP9 is electrically coupled to a reference voltage Vref. A source of MP9 is electrically connected to a node 550. A drain of MP9 is electrically connected to signal ground. A drain of MP6 is electrically connected to the node 550 such that the node 550 is electrically connected with the drain of MP6 and with the source of MP9. The node 550 is electrically connected to a negative input of the OTA.

Thus, the NMOS M1 controlling transistor is now connected to the tail node nₜₐᵢₗ of the preamplifier differential pair 510. The noise injected by M1 appears at the output as common-mode and is rejected differentially. If the uncontrolled output common-mode voltage of the preamplifier is too high, then M1 is driven stronger, and it takes some of the current in the bias transistor MP3 thus bringing the output common-mode voltage down. If the output common-mode voltage is lower than needed, then M1 sees reduced drive at its gate and more bias current goes into the load resistors RL1, RL2 increasing the output common-mode voltage.

As a result, the nominal bias current through MP1, MP2, RL1, and RL2 is still the same as initially designed for gain and bandwidth, because the output common-mode voltage is kept the same, but this comes at the cost of increased overall power consumption, since the tail current has to be high enough to provide also for the current in M1.

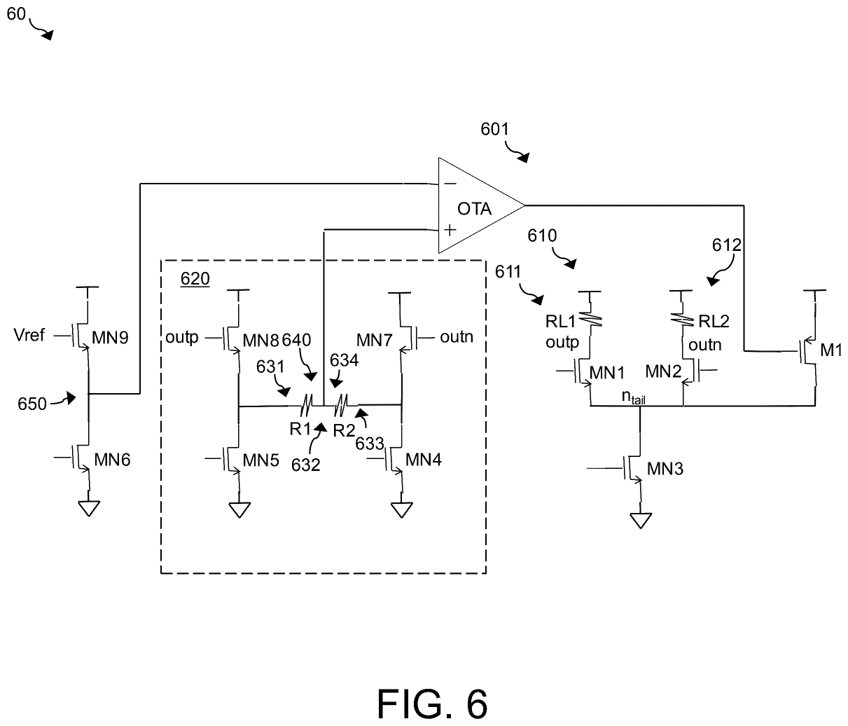

FIG. 6 is a circuit diagram of a preamplifier 60 according to one or more embodiments. The preamplifier 60 includes an OTA, a PMOS transistor M1, a plurality of NMOS transistors MN1-MN9, load resistors RL1, RL2, and resistors R1, R2. The preamplifiers 50, 60 are the same except that the transistors are of the opposite type in preamplifier 60 than in preamplifier 50.

The output 601 of the OTA is electrically connected to a gate of the PMOS transistor M1. A source of M1 is electrically connected or electrically coupled to a tail node nₜₐᵢₗ. A drain of M1 is electrically connected to a supply voltage. A long-tailed differential pair 610 is electrically connected to the tail node nₜₐᵢₗ. A first side 611 of the differential pair 610 includes MN1 and a first load resistor RL1 electrically connected in series with a drain of MN1. The first load resistor RL1 is also electrically connected in series with a supply voltage. A second side 612 of the differential pair 610 includes MN2 and a second load resistor RL2 electrically connected in series with a drain of MN2. The second load resistor RL2 is also electrically connected in series with a supply voltage. The drain of MN1 has a positive output voltage outp. The drain of MN2 has a negative output voltage outn. The first and second load resistors RL1, RL2 are the same or substantially the same. A drain of bias transistor MN3 is electrically connected in series with the tail node nₜₐᵢₗ. A source of bias transistor MN3 is electrically connected to signal ground.

A feedback circuit 620 is electrically coupled to the output voltages outp, outn. The feedback circuit 620 includes NMOS transistors MN4-MN9 and resistors R1, R2.

A gate of MN8 is electrically coupled to the output voltage outp. A source of MN8 is electrically connected to a first terminal 631 of the resistor R1 and to a drain of MN5. A drain of MN8 is electrically connected to a supply voltage. A gate of MN7 is electrically coupled to the output voltage outn. A source of MN7 is electrically connected to a first terminal 633 of the resistor R2 and to a drain of MN4. A second terminal 632 of the first resistor R1 and a second terminal 634 of the second resistor R2 are electrically connected to a common-mode node 640. The common-mode node 640 is electrically connected in series with the second terminal 632 of the first resistor R1 and the second terminal 634 of the second resistor R2. The first and second resistors R1, R2 can be the same or substantially the same. The common-mode node 640 is electrically connected to a positive input of the OTA. The NMOS transistors MN4, MN5, MN7, and MN8 and resistors R1, R2 extract the preamplifier output common-mode voltage and feed it back to the OTA.

A gate of MN9 is electrically coupled to the reference voltage Vref. A source of MP9 is electrically connected to a node 650. A drain of MN9 is electrically connected to a supply voltage. A drain of MN6 is electrically connected to the node 650 such that the node 650 is electrically connected with the drain of MN6 and with the source of MN9. The node 650 is electrically connected to a negative input of the OTA.

Thus, the PMOS M1 controlling transistor is now connected to the tail node nₜₐᵢₗ of the preamplifier differential pair 610. The noise injected by M1 appears at the output as common-mode and is rejected differentially. If the common-mode voltage of the preamplifier is too high, then M1 sees reduced drive at its gate and more current goes into the load resistors RL1 and RL2 reducing the output common-mode voltage. If the output common-mode voltage is too low, then M1 is driven stronger, and it takes some of the current in the bias transistor MN3 thus increasing the output common-mode voltage.

As a result, the nominal bias current through MN1, MN2, RL1, and RL2 is still the same as initially designed for gain and bandwidth, because the output common-mode voltage is kept the same, but this comes at the cost of increased overall power consumption, since the tail current has to be high enough to provide also for the current in M1.

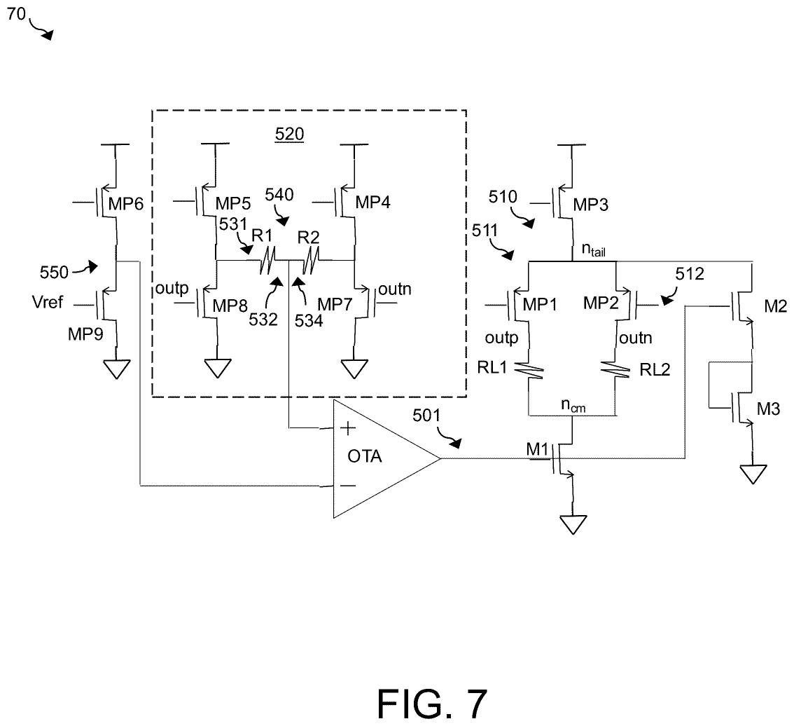

FIG. 7 is a circuit diagram of a preamplifier 70 according to one or more embodiments. Preamplifier 70 can be used to avoid the higher current consumption and assure large enough range of control for the output common-mode voltage and at the same time injecting only noise that is common-mode at the preamplifier output. Preamplifier 70 includes an OTA, a plurality of NMOS transistor M1-M3, a plurality of PMOS transistors MP1-MP9, load resistors RL1, RL2, and resistors R1, R2. Preamplifier 70 is the same as preamplifier 50 except that preamplifier 70 includes NMOS transistors M2 and M3 and the electrical connection of NMOS transistor M1 is different, as described below.

The long-tailed differential pair 510 is electrically connected to the tail node nₜₐᵢₗ and a common-mode node n_{cm}. A drain of the NMOS transistor M1 is electrically connected to the common-mode node n_{cm}. A gate of the NMOS transistor M1 is electrically connected to the output 501 of the OTA. A source of the NMOS transistor M1 is electrically connected to signal ground.

A gate of the NMOS transistor M2 is electrically connected to the output 501 of the OTA. A drain of the NMOS transistor M2 is electrically connected to the tail node nₜₐᵢₗ. A drain and a gate of the NMOS transistor M3 are electrically connected to a source of the NMOS transistor M2. A source of the NMOS transistor M3 is electrically connected to signal ground.

A first terminal of the first load resistor RL1 is electrically connected to the drain of the PMOS transistor MP1. A second terminal of the first load resistor RL1 is electrically connected to the common-mode node n_{cm}. A first terminal of the second load resistor RL2 is electrically connected to the drain of the PMOS transistor MP2. A second terminal of the second load resistor RL2 is electrically connected to the common-mode node n_{cm}.

The common-mode control loop works primarily with NMOS transistor M1 for cases when the uncontrolled preamplifier output common-mode voltage is lower than nominal and also not too much higher than its nominal value. For these cases NMOS transistor M2 is mostly off since it needs higher gate voltage because its source is shifted up by the diode-connected NMOS transistor M3. NMOS transistor M2 only starts conducting when the OTA tries to drive M1 stronger by increasing its gate voltage in the case of high uncontrolled preamplifier output common-mode voltage. If NMOS transistor M2 were not present, NMOS transistor M1 would have been driven into the triode region, for example as described with respect to preamplifier 50. With the presence of NMOS transistor M2, though NMOS transistor M1 doesn't really need to be driven all that strong because NMOS transistor M2 now takes some of the tail current away and helps bring down to normal the output common mode voltage. Since NMOS transistor M2 only comes into the picture at the higher end of the control range and it works together with NMOS transistor M1, the bias current in the tail device MP3 doesn't need to be increased above the value needed to provide for nominal preamplifier gain and bandwidth, so power consumption is not increased.

Because bias current programmability can be provided by changing the size of MP3 and the corresponding values of RL1, R12, it is preferrable to control the output common-mode voltage from the NMOS side and keep the two functions separated. Note that the stability requirements of the common-mode feedback loop are not described because those skilled in the art would know what contractions are needed to assure loop stability.

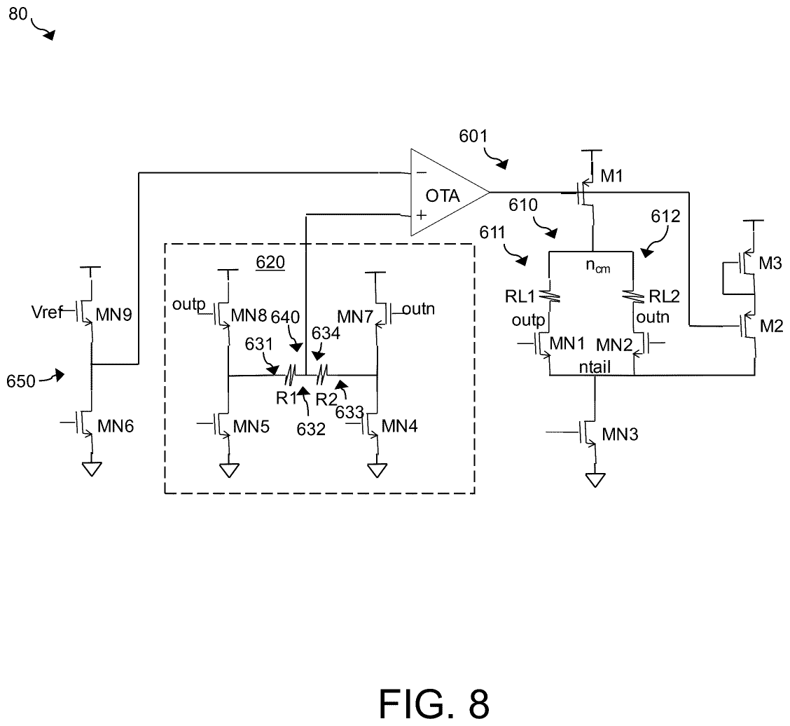

FIG. 8 is a circuit diagram of a preamplifier 80 according to one or more embodiments. The preamplifier 80 includes an OTA, a plurality of PMOS transistor M1-M3, a plurality of NMOS transistors MN1-MN9, load resistors RL1, RL2, and resistors R1, R2. The preamplifiers 70, 80 are the same except that the transistors are of the opposite type in preamplifier 80 than in preamplifier 70. In addition, preamplifier 80 is the same as preamplifier 60 except that preamplifier 80 includes PMOS transistors M2 and M3 and the electrical connection of PMOS transistor M1 is different, as described below.

The long-tailed differential pair 610 is electrically connected to the tail node nₜₐᵢₗ and a common-mode node n_{cm}. A drain of the PMOS transistor M1 is electrically connected to the common-mode node n_{cm}. A gate of the PMOS transistor M1 is electrically connected to the output 601 of the OTA.

A gate of the PMOS transistor M2 is electrically connected to the output 601 of the OTA. A drain of the PMOS transistor M2 is electrically connected to the tail node nₜₐᵢₗ. A drain and a gate of the PMOS transistor M3 are electrically connected to a source of the PMOS transistor M2.

A first terminal of the first load resistor RL1 is electrically connected to the drain of the NMOS transistor MN1. A second terminal of the first load resistor RL1 is electrically connected to the common-mode node n_{cm}. A first terminal of the second load resistor RL2 is electrically connected to the drain of the NMOS transistor MN2. A second terminal of the second load resistor RL2 is electrically connected to the common-mode node n_{cm}.

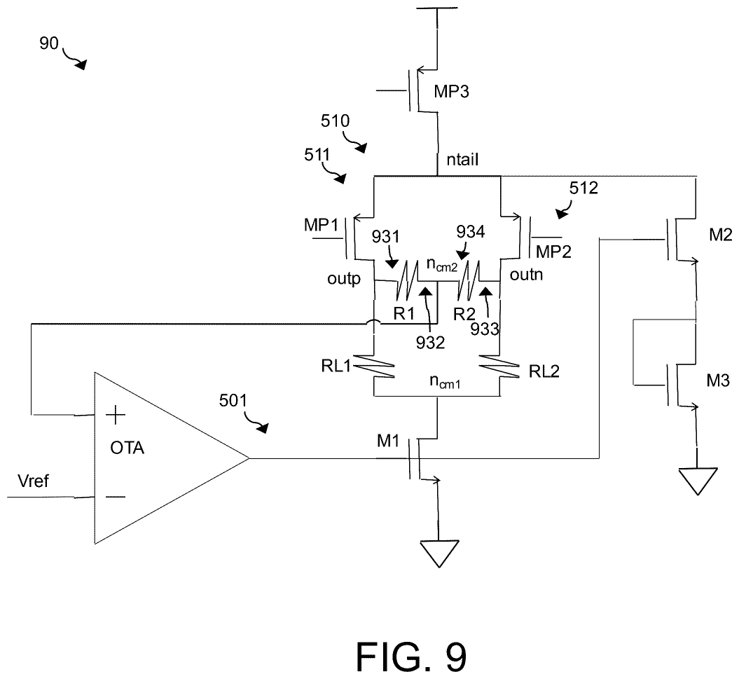

FIG. 9 is a circuit diagram of a preamplifier 90 according to one or more embodiments. Preamplifier 90 is an alternative embodiment of preamplifier 70. Preamplifier 90 includes an OTA, a plurality of NMOS transistor M1-M3, a plurality of PMOS transistors MP1-MP3, load resistors RL1, RL2, and resistors R1, R2.

In preamplifier 90, the long-tailed differential pair 510 includes a first common-mode node n_{cm1} and a second common-mode node n_{cm2}. The first common-mode node n_{cm1} is electrically connected to the first and second load resistors RL1, RL2 and to the drain of the NMOS transistor M1. A first terminal of the first load resistor RL1 is electrically connected to the drain of the PMOS transistor MP1. A second terminal of the first load resistor RL1 is electrically connected to the first common-mode node n_{cm1}. A first terminal of the second load resistor RL2 is electrically connected to the drain of the PMOS transistor MP2. A second terminal of the second load resistor RL2 is electrically connected to the first common-mode node n_{cm1}.

The second common-mode node n_{cm2} is electrically connected to the respective second terminals 932, 934 of the first and second resistors R1, R2 and to the positive input of the OTA. The respective first terminals 931, 933 of the first and second resistors R1, R2 are electrically connected to the respective drains of the PMOS transistors MP1, MP2. The negative input of the OTA is electrically connected to a reference voltage Vref.

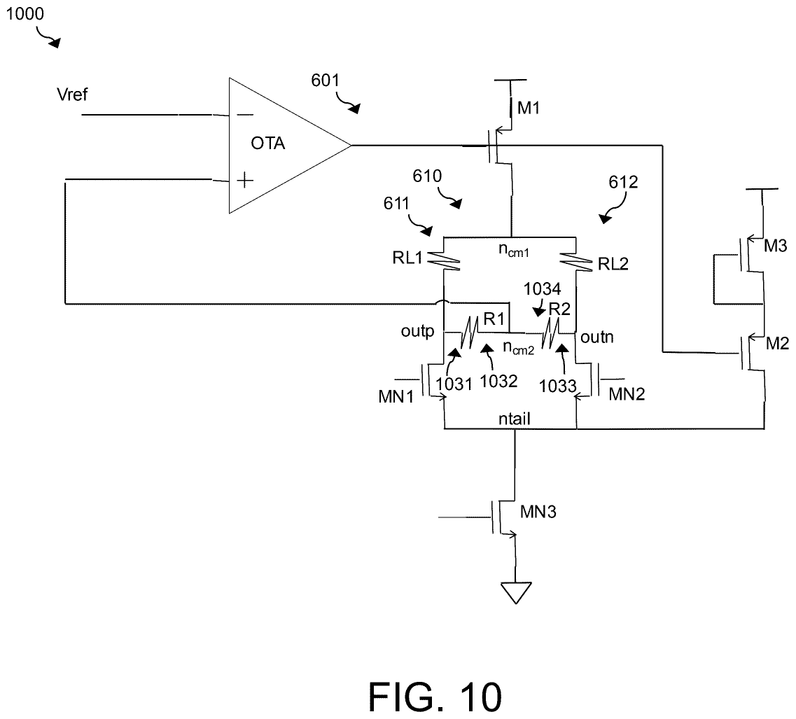

FIG. 10 is a circuit diagram of a preamplifier 1000 according to one or more embodiments. Preamplifier 1000 is an alternative embodiment of preamplifier 80. In addition, preamplifier 1000 is the same as preamplifier 90 except that the transistors are of the opposite type in preamplifier 1000 than in preamplifier 90. Preamplifier 90 includes an OTA, a plurality of PMOS transistor M1-M3, a plurality of NMOS transistors MN1-MN3, load resistors RL1, RL2, and resistors R1, R2.

In preamplifier 1000, the long-tailed differential pair 610 includes a first common-mode node n_{cm1} and a second common-mode node n_{cm2}. The first common-mode node n_{cm1} is electrically connected to the first and second load resistors RL1, RL2 and to the drain of the PMOS transistor M1. A first terminal of the first load resistor RL1 is electrically connected to the drain of the NMOS transistor MN1. A second terminal of the first load resistor RL1 is electrically connected to the first common-mode node n_{cm1}. A first terminal of the second load resistor RL2 is electrically connected to the drain of the NMOS transistor MN2. A second terminal of the second load resistor RL2 is electrically connected to the first common-mode node n_{cm1}.

The second common-mode node n_{cm2} is electrically connected to the respective second terminals 1032, 1034 of the first and second resistors R1, R2 and to the positive input of the OTA. The respective first terminals 1031, 1033 of the first and second resistors R1, R2 are electrically connected to the respective drains of the NMOS transistors MN1, MN2. The negative input of the OTA is electrically connected to a reference voltage Vref.

A slight disadvantage of preamplifiers 90, 1000 is the increased loading at outp and outm caused by the connection of R1 and R2 to the drain of PMOS transistors MP1, MP2 (preamplifier 90) or to the drain of the NMOS transistors MN1, MN2 (preamplifier 1000). But if R1 and R2 are much higher in value compared to RL1 and RL2 this problem becomes less significant.

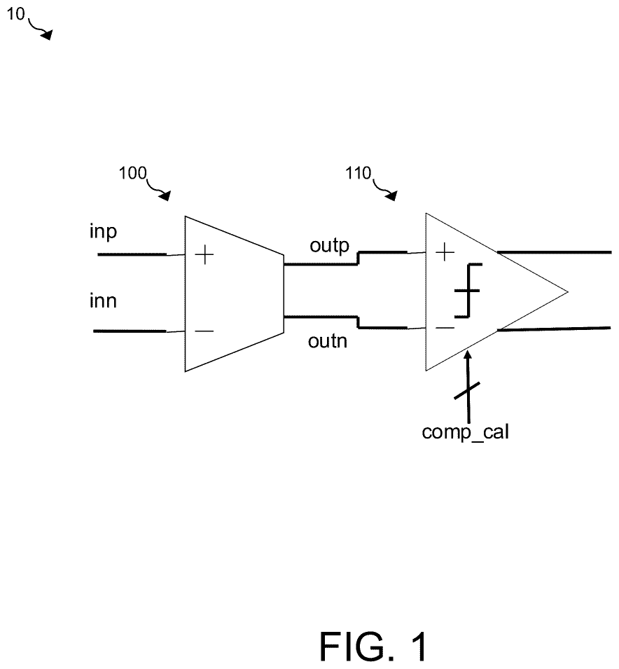

In example implementations, the preamplifier 100 of the ADC comparator 10 (FIG. 1) can comprise a preamplifier 50, 60, 70, 80, 90, or 1000 as described herein. Thus, the positive and negative output voltages outp, outn of the preamplifier 50, 60, 70, 80, 90, or 1000 can be electrically coupled to respective inputs of the clocked latch 110. In other example implementations, a preamplifier 50, 60, 70, 80, 90, or 1000 can be electrically coupled to other circuits.

The invention should not be considered limited to the particular embodiments described above, but rather should be understood to cover all aspects of the invention as fairly set out in the attached claims. Various modifications, equivalent processes, as well as numerous structures to which the invention may be applicable, will be apparent to those skilled in the art to which the invention is directed upon review of this disclosure. The claims are intended to cover such modifications and equivalents.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

What is claimed is:

1. A preamplifier comprising:
an operational transconductance amplifier (OTA) having first and second inputs and an output;
a first-type metal-oxide-semiconductor (MOS) transistor have a gate electrically coupled to the output of the OTA;
a first second-type MOS transistor;
a second second-type MOS transistor, the first and second second-type MOS transistors electrically connected in parallel with each other,
a first load resistor electrically connected in series with a drain of the first second-type MOS transistor, the drain of the first second-type MOS transistor having a first output voltage;
a second load resistor electrically connected in series with a drain of the second second-type MOS transistor, the drain of the second second-type MOS transistor having a second output voltage;
a third second-type MOS transistor;
a tail node electrically connected to a source of the first second-type MOS transistor, a source of the second second-type POS transistor, and a drain of the third second-type MOS transistor;
a common-mode feedback circuit electrically coupled to the first and second output voltages and to the first input of the OTA; and
a reference voltage electrically coupled to the second input of the OTA,
wherein the first-type MOS transistor is of an opposite type to each second-type MOS transistor.

2. The preamplifier of claim 1, wherein the first-type MOS transistor is an N-channel MOS (NMOS) transistor and each second-type MOS transistor is a P-channel MOS (PMOS) transistor.

3. The preamplifier of claim 1, wherein the first-type MOS transistor is a P-channel MOS (PMOS) transistor and each second-type MOS transistor is an N-channel MOS (NMOS) transistor.

4. The preamplifier of claim 1, wherein the common-mode feedback circuit comprises:
a fourth second-type MOS transistor having a gate electrically coupled to the first output voltage;
a fifth second-type MOS transistor having a gate electrically coupled to the second output voltage;
a sixth second-type MOS transistor;
a seventh second-type MOS transistor;
a first resistor having first and second terminals, the first terminal electrically connected to a source of the fourth second-type MOS transistor and to a drain of the sixth second-type MOS transistor, the second terminal electrically connected to a common-mode node; and
a second resistor having first and second terminals, the first terminal of the second resistor electrically connected to a source of the fifth second-type MOS transistor and to a drain of the seventh second-type MOS transistor, the second terminal electrically connected to the common-mode node, the common-mode node electrically coupled to the first input of the OTA.

5. The preamplifier of claim 4, further comprising:
an eighth second-type MOS transistor having a gate electrically coupled to the reference voltage and a source electrically connected to a reference node; and
a nineth second-type MOS transistor having a drain electrically connected to the reference node, the reference node electrically coupled to the second input of the OTA.

6. The preamplifier of claim 1, wherein the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

7. A comparator for an analog-to-digital converter comprising the preamplifier of claim 1 and a clocked latch, wherein the first and second output voltages are electrically coupled to first and second inputs, respectively, of the clocked latch.

8. A preamplifier comprising:
an operational transconductance amplifier (OTA) having first and second inputs and an output;
a first first-type metal-oxide-semiconductor (MOS) transistor have a gate electrically coupled to the output of the OTA;
a first second-type MOS transistor;
a second second-type MOS transistor, the first and second second-type MOS transistors electrically connected in parallel with each other,
a first load resistor electrically connected in series with a drain of the first second-type MOS transistor, the drain of the first second-type MOS transistor having a first output voltage;
a second load resistor electrically connected in series with a drain of the second second-type MOS transistor, the drain of the second second-type MOS transistor having a second output voltage;
a third second-type MOS transistor;
a tail node electrically connected to a source of the first second-type MOS transistor, a source of the second second-type POS transistor, and a drain of the third second-type MOS transistor;
a second first-type MOS transistor have a gate electrically coupled to the output of the OTA and a drain electrically connected to the tail node;
a third first-type MOS transistor have a gate and a drain electrically connected to a source of the second first-type MOS transistor;
a common-mode feedback circuit electrically coupled to the first and second output voltages and to the first input of the OTA; and
a reference voltage electrically coupled to the second input of the OTA,
wherein each first-type MOS transistor is of an opposite type to each second-type MOS transistor.

9. The preamplifier of claim 8, wherein each first-type MOS transistor is an N-channel MOS (NMOS) transistor and each second-type MOS transistor is a P-channel MOS (PMOS) transistor.

10. The preamplifier of claim 8, wherein each first-type MOS transistor is a P-channel MOS (PMOS) transistor and each second-type MOS transistor is an N-channel MOS (NMOS) transistor.

11. The preamplifier of claim 8, wherein:
the common-mode node is a first common-mode node, and
the common-mode feedback circuit comprises:
a fourth second-type MOS transistor having a gate electrically coupled to the first output voltage;
a fifth second-type MOS transistor having a gate electrically coupled to the second output voltage;
a sixth second-type MOS transistor;
a seventh second-type MOS transistor;
a first resistor having first and second terminals, the first terminal electrically connected to a source of the fourth second-type MOS transistor and to a drain of the sixth second-type MOS transistor, the second terminal electrically connected to a second common-mode node; and
a second resistor having first and second terminals, the first terminal of the second resistor electrically connected to a source of the fifth second-type MOS transistor and to a drain of the seventh second-type MOS transistor, the second terminal electrically connected to the second common-mode node, the second common-mode node electrically coupled to the first input of the OTA.

12. The preamplifier of claim 11, further comprising:
an eighth second-type MOS transistor having a gate electrically coupled to the reference voltage and a source electrically connected to a reference node; and
a nineth second-type MOS transistor having a drain electrically connected to the reference node, the reference node electrically coupled to the second input of the OTA.

13. The preamplifier of claim 8, wherein the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

14. A comparator for an analog-to-digital converter comprising the preamplifier of claim 8 and a clocked latch, wherein the first and second output voltages are electrically coupled to first and second inputs, respectively, of the clocked latch.

15. A preamplifier comprising:
an operational transconductance amplifier (OTA) having first and second inputs and an output;
a first first-type metal-oxide-semiconductor (MOS) transistor have a gate electrically coupled to the output of the OTA;
a first second-type MOS transistor;
a second second-type MOS transistor, the first and second second-type MOS transistors electrically connected in parallel with each other;
a first load resistor electrically connected in series with a drain of the first second-type MOS transistor, the drain of the first second-type MOS transistor having a first output voltage;
a second load resistor electrically connected in series with a drain of the second second-type MOS transistor, the drain of the second second-type MOS transistor having a second output voltage;
a third second-type MOS transistor;
a tail node electrically connected to a source of the first second-type MOS transistor, a source of the second second-type POS transistor, and a drain of the third second-type MOS transistor;
a second first-type MOS transistor have a gate electrically coupled to the output of the OTA and a drain electrically connected to the tail node;
a third first-type MOS transistor have a gate and a drain electrically connected to a source of the second first-type MOS transistor;
a first common-mode node electrically connected to the first and second load resistors and to a drain of the first first-type MOS transistor;
a first resistor having a first terminal electrically connected to a drain of the first second-type MOS transistor;
a second resistor having a second terminal electrically connected to a drain of the second second-type MOS transistor;
a second common-mode node electrically connected to a second terminal of the first resistor, a second terminal of the second resistor, and the first input of the OTA; and
a reference voltage electrically coupled to the second input of the OTA,
wherein each first-type MOS transistor is of an opposite type than each second-type MOS transistor.

16. The preamplifier of claim 15, wherein each first-type MOS transistor is an N-channel MOS (NMOS) transistor and each second-type MOS transistor is a P-channel MOS (PMOS) transistor.

17. The preamplifier of claim 15, wherein each first-type MOS transistor is a P-channel MOS (PMOS) transistor and each second-type MOS transistor is an N-channel MOS (NMOS) transistor.

18. The preamplifier of claim 15, wherein the first second-type MOS transistor, the second second-type MOS transistor, the first load resistor, and the second load resistor are configured as a long-tailed differential pair, the long-tailed differential pair having a first side that includes the first second-type MOS transistor and the first load resistor and a second side that includes the second second-type MOS transistor and the second load resistor.

19. A comparator for an analog-to-digital converter comprising the preamplifier of claim 15 and a clocked latch, wherein the first and second output voltages are electrically coupled to first and second inputs, respectively, of the clocked latch.
